(19) United States
(12) Patent Application Publication
(10) Pub. No.: US 2014/0021504 A1
(43) Pub. Date: Jan. 23, 2014

(54) LIGHT EMITTING DEVICE

(71) Applicant: PANASONIC CORPORATION, Osaka (JP)

(72) Inventor: Toshikazu ONISHI, Osaka (JP)

(73) Assignee: PANASONIC CORPORATION, Osaka (JP)

(21) Appl. No.: 14/038,697

(22) Filed: Sep. 26, 2013

Related U.S. Application Data
(63) Continuation of application No. PCT/JP2011/004397, filed on Aug. 3, 2011.

(30) Foreign Application Priority Data
Mar. 30, 2011 (JP) 2011-076002

(51) Int. Cl. H01L 33/50

(52) U.S. Cl. CPC H01L 33/505; B82Y 20/00
USPC 257/98; 977/774

(57) ABSTRACT

A light emitting device includes: a light emitting section including an active layer configured to emit light by application of a voltage; and a thin metal film disposed on a region of the light emitting section irradiated with the light. The thin metal film has a plurality of openings each having a diameter that is smaller than a wavelength of the light, and at least one phosphor is placed in each of the openings.

### CROSS-REFERENCE TO RELATED APPLICATIONS

This is a continuation of International Application No. PCT/JP2011/004397 filed on Aug. 3, 2011, which claims priority to Japanese Patent Application No. 2011-076002 filed on Mar. 30, 2011. The entire disclosures of these applications are incorporated by reference herein.

### BACKGROUND

The present disclosure relates to light emitting devices serving as white light sources, and more particularly relates to a light emitting device emitting white light by mixing light beams emitted from phosphors excited by, e.g., a light emitting diode or a surface emitting laser.

Solid-state light emitting devices capable of emitting white light are small devices with high efficiency and low power consumption, and have been expected as next-generation light sources that will be, for example, alternatives to currently used fluorescent lamps or incandescent lamps. Among such solid-state light emitting devices, light emitting diodes (LEDs) are highly monochromatic light sources, and thus, in order to obtain white light using LEDs, at least two colors of light need to be generated, and be mixed.

Japanese Patent Publication No. 2000-223750 describes, as a conventional white light emitting device, a device including a blue LED encapsulated by a transparent resin containing yttrium aluminum garnet (YAG) phosphors. FIG. 4 is a cross-sectional view of the conventional white light emitting device described in Japanese Patent Publication No. 2000-223750. As illustrated in FIG. 4, in a white light emitting device 100, a blue LED 103 is mounted on a substrate 104 with a mounting member 108 interposed therebetween. Electrodes of the blue LED 103 are electrically connected through wires 107 to lead electrodes 105 and 106 provided on the substrate 104. The blue LED 103 and the wires 107 are encapsulated on the substrate 104 by a transparent resin 101 containing YAG phosphors 102.

In the white light emitting device 100 illustrated in FIG. 4, the YAG phosphors 102 absorb part of light emitted from the blue LED 103, and emit fluorescence in the yellow wavelength range. The two colors of light are mixed, and visually white light exits from the white light emitting device 100.

However, the conventional white light emitting device 100 has a problem where the luminous efficacy of the phosphors is low, and a problem where since the light sources of the two colors are used, pure white light cannot be obtained, and thus, low color rendering is exhibited.

To address the problems, in recent years, the development of microfabrication technology has enabled the manufacture of nanophosphors each having a minute particle size. The size of each of the nanophosphors is smaller than the light wavelength, and thus, the use of the nanophosphors can be expected to reduce the scattering of light as compared with the use of conventional phosphors, and to improve the luminous efficacy. When three colors of nanophosphors having emission wavelengths of three primary colors, i.e., red, green, and blue, are used, white light with high color rendering can be obtained. For example, Japanese Translation of PCT International Application No. 2008-546877 describes a light emitting optical device using nanoparticles as a wavelength conversion material.

### SUMMARY

However, since nanophosphors each have a small particle size, the proportion of surface defects in nanophosphors (the number of surface defects per unit volume) is higher than that of surface defects in bulk phosphors. The surface defects causes nonradiative transition, thereby decreasing the luminous efficacy. When the surfaces of nanophosphors are modified to remove defects, this causes another problem where the device fabrication process is complicated, and cost reduction becomes difficult, while improving the luminous efficacy.

It is therefore an object of the present invention to provide a white light emitting device with high luminous efficacy.

In order to achieve the object, a light emitting device according to the present disclosure includes: a light emitting section including an active layer configured to emit light by application of a voltage; and a thin metal film disposed on a region of the light emitting section irradiated with the light. The thin metal film has a plurality of openings each having a diameter that is smaller than a wavelength of the light, and at least one phosphor is placed in each of the openings.

According to the light emitting device of the present disclosure, light emitted by the active layer and light emitted by the phosphor excited by the light are mixed, thereby emitting white light. In this case, the light emitted from the active layer produces surface plasmons in the thin metal film, and thus, the electric field enhanced by the surface plasmons is obtained. Therefore, the phosphor placed in each of the openings of the thin metal film is strongly excited to emit light with high intensity. This can provide a white light emitting device with high luminous efficacy.

In the light emitting device according to the present disclosure, the phosphor may be a particle having a size equal to or less than about 100 nm. This can reduce the light scattering caused by the phosphor, thereby improving the light extraction efficiency.

In the light emitting device of the present disclosure, the openings may each have a diameter greater than or equal to about 50 nm and equal to or less than 200 nm. This enables efficient production of the above-described surface plasmons.

In the light emitting device of the present disclosure, the at least one phosphor may include three types of phosphors emitting light in blue, green, and red wavelength regions. This enables utilization of fluorescences of three primary colors, and thus, white light with high color rendering can be obtained. In this case, λact may be less than λ1, λact may be less than λ2, and λact may be less than λ3, where λact represents a wavelength of the light emitted by the active layer, λ1 represents an emission wavelength of one of the phosphors emitting light in the blue wavelength region, λ2 represents an emission wavelength of another one of the phosphors emitting light in the green wavelength region, and λ3 represents an emission wavelength of the other one of the phosphors emitting light in the red wavelength region. This allows light generated by the active layer to efficiently excite the phosphor.

In the light emitting device according to the present disclosure, the phosphor may be a quantum dot. This can provide fluorescence having a small half-width. In this case, the quantum dot may have a size greater than or equal to about 1 nm and equal to or less than 20 nm. This can provide fluorescence of visible wavelength.

In the light emitting device according to the present disclosure, the light emitting section may be a surface emitting laser, the thin metal film may be formed on the surface emitting laser, and the phosphor may be excited by laser light generated by the surface emitting laser. This can reduce, e.g., the waveguide loss or coupling loss between the light emitting section and the phosphor, and can simplify the device fabrication process to reduce cost.

In the light emitting device according to the present disclosure, the light emitting section may be a light emitting diode, the thin metal film may be formed on the light emitting diode, and the phosphor may be excited by light generated by the light emitting diode. This can reduce, e.g., the waveguide loss or coupling loss between the light emitting section and the phosphor, and can simplify the device fabrication process to reduce cost.

According to the present disclosure, a white light emitting device with high luminous efficacy can be provided.

### BRIEF DESCRIPTION OF THE DRAWINGS

FIGS. 1A and 1B are a plan view and a cross-sectional view, respectively, of a light emitting device according to an embodiment.

FIG. 2 is a diagram schematically illustrating a process of recombining an electron and a hole in a phosphor of the light emitting device according to the embodiment.

FIG. 3 is a graph illustrating the excitation intensity dependence of the transition probability in the recombination process illustrated in FIG. 2.

FIG. 4 is a cross-sectional view of a conventional white light emitting device.

### DETAILED DESCRIPTION

A light emitting device according to an embodiment of the present disclosure will be described with reference to the drawings.

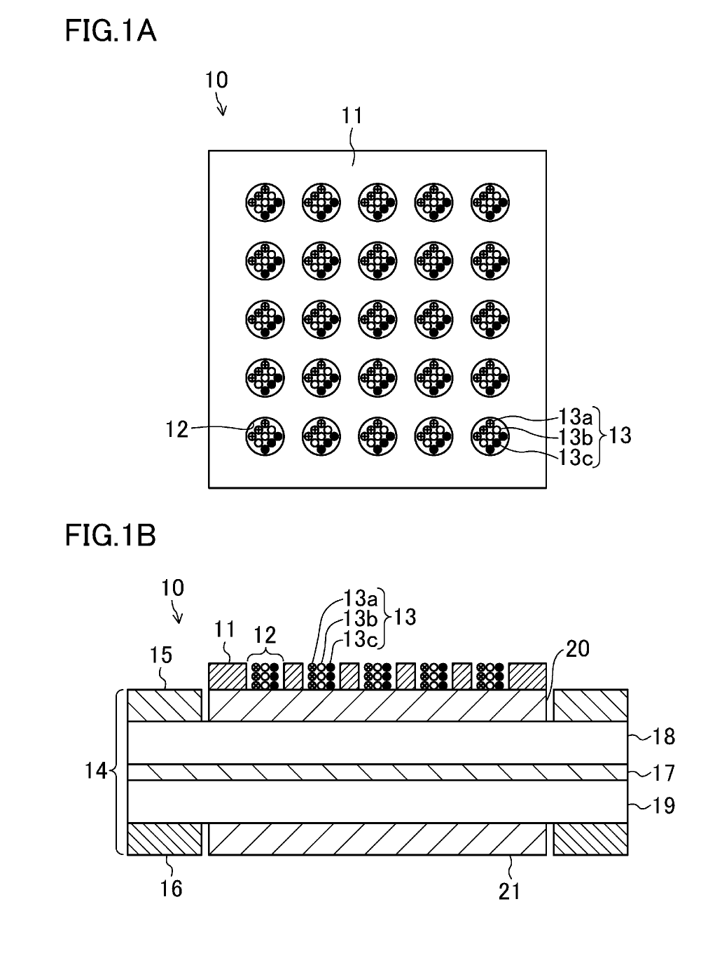

FIGS. 1A and 1B are a plan view and a cross-sectional view, respectively of a light emitting device according to this embodiment. Specifically, the light emitting device is a white light emitting device that emits white light by mixing light beams emitted from phosphors excited by, e.g., a light emitting diode or a surface emitting laser.

As illustrated in FIGS. 1A and 1B, a white light emitting device 10 of this embodiment includes a light emitting section 14, such as an AlGaInN-based surface emitting laser (vertical cavity surface emitting laser: VCSEL), and a thin metal film 11 disposed on at least a region of the light emitting section 14 irradiated with light, and made of, e.g., gold (Au) or silver (Ag). The thin metal film 11 is provided with a plurality of periodic minute openings 12 each having a diameter that is smaller than the wavelength of the light (i.e., the oscillation wavelength of the light emitting section 14). Specifically, when the oscillation wavelength of the light emitting section 14 is, for example, 405 nm, surface plasmons can be excited by a first grating coupling by setting each of the intervals at which the minute openings 12 are spaced at 255 nm. Alternatively, surface plasmons can be excited by a second grating coupling by setting the interval at which the minute openings 12 are spaced at 515 nm. A plurality of phosphors 13, more specifically, three types of quantum dot phosphors 13a, 13b, and 13c having respective blue, green, and red emission wavelengths are placed in each of the minute openings 12. This enables utilization of fluorescences of three primary colors, and thus, white light with high color rendering can be obtained. Here, the oscillation wavelength of the light emitting section 14 is set at a wavelength that is shorter than the emission wavelength of each of the quantum dot phosphors 13a, 13b, and 13c, and thus, the phosphors 13 are efficiently excited by light generated by the light emitting section 14.

The light emitting section 14 includes an active layer 17 configured to emit light by application of a voltage, an n-type spacer layer 18 formed on the active layer 17, an upper distributed feedback reflector (DBR) 20 formed on a portion of the n-type spacer layer 18 except an outer portion thereof, an n-side electrode 15 formed on the outer portion of the n-type spacer layer 18, a p-type spacer layer 19 formed under the active layer 17, a lower DBR 21 formed under a portion of the p-type spacer layer 19 except an outer portion thereof, and a p-side electrode 16 formed under the outer portion of the p-type spacer layer 19.

The thickness of the thin metal film 11 may be, for example, about 100 nm. This enables efficient production of surface plasmons, and enables efficient extraction of light generated by the phosphors 13. The thickness of the thin metal film 11 is preferably greater than or equal to about 50 nm and equal to or less than about 500 nm. The reason for this is that when the thickness of the thin metal film 11 is less than about 50 nm, light passes through the thin metal film 11, and the efficiency of producing surface plasmons decreases, and when the thickness of the thin metal film 11 is greater than about 500 nm, the efficiency of extracting light generated by the phosphors 13 decreases.

The shape of each of the minute openings 12 as viewed in plan may be circular, e.g., as illustrated in FIG. 1A, is not limited to the circular shape, and may be, for example, oval or square. When an isotropic shape, such as a circular shape, is used as the opening shape, isotropic light emission can be obtained, and when an anisotropic shape, such as an oval shape or a square shape, is used as the opening shape, polarization of light emission can be controlled.

The diameter of each of the minute openings 12 is not specifically limited as long as it is smaller than the oscillation wavelength of the light emitting section 14. However, when the minute openings 12 each have a diameter greater than or equal to about 50 nm and equal to or less than about 200 nm, surface plasmons can be efficiently produced in the thin metal film 11. The “diameter of each of the minute openings 12” denotes “the largest size of the minute opening 12.” Specifically, when the shape of the minute opening 12 as viewed in plan is perfectly circular, the “diameter of each of the minute openings 12” denotes the “diameter” thereof; when the shape of the minute opening 12 as viewed in plan is oval, the “diameter of each of the minute openings 12” denotes the “length of the major axis” thereof; and when the shape of the minute opening 12 as viewed in plan is square, the “diameter of each of the minute openings 12” denotes the “diagonal length” thereof.

The size of each of the phosphors 13 is not specifically limited as long as it is smaller than the diameter of each of the minute openings 12. However, when the phosphors 13 are particles each having a size equal to or less than about 100 nm, this can reduce the light scattering caused by the phosphors 13, thereby improving the light extraction efficiency.

When, similarly to this embodiment, the quantum dot phosphors 13a, 13b, and 13c are used as the phosphors 13, fluorescence having a small half-width can be obtained. Here, when the quantum dot phosphors 13a, 13b, and 13c each have a size greater than or equal to about 1 nm and equal to or less than about 20 nm, fluorescence of visible wavelength can be obtained. For example, cadmium selenide (CdSe) can be used as a material of each of the quantum dot phosphors 13a, 13b, and 13c. A suspension obtained by dispersing the quantum dot phosphors 13a, 13b, and 13c into a solvent, such as water or an organic solvent, is prepared, and the quantum dot phosphors 13a, 13b, and 13c can be placed in each of the minute openings 12 by applying the suspension onto the thin metal film 11 by a method, such as a method using a dispenser or spin coating.

In the white light emitting device 10 of this embodiment, when a voltage is applied to the light emitting section (AlGaInN-based VCSEL) 14 to pass current therethrough, light is produced in the active layer 17, and the DBRs 17 and 18 formed above and below the active layer 17 serve as a resonator, resulting in laser oscillation. Laser light emitted by the white light emitting device 10 produces surface plasmons through the periodicity of the minute openings 12 formed in the thin metal film 11. The electric field enhanced by the surface plasmons is obtained, and thus, the phosphors 13 (the quantum dot phosphors 13a, 13b, and 13c) placed in each of the minute openings 12 of the thin metal film 11 are strongly excited to provide blue, green, and red light emissions with high intensity. This can achieve a white light emitting device with high luminous efficacy.

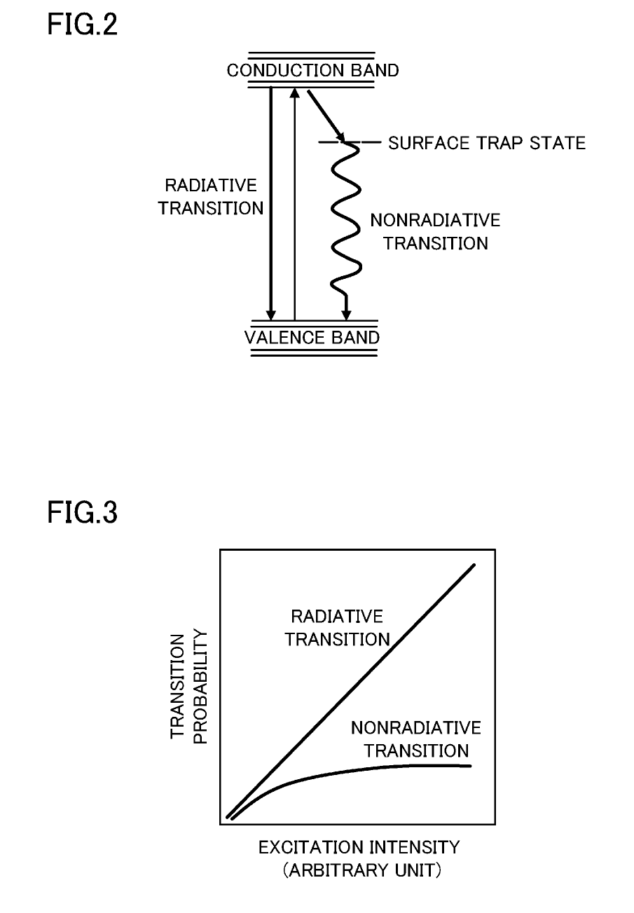

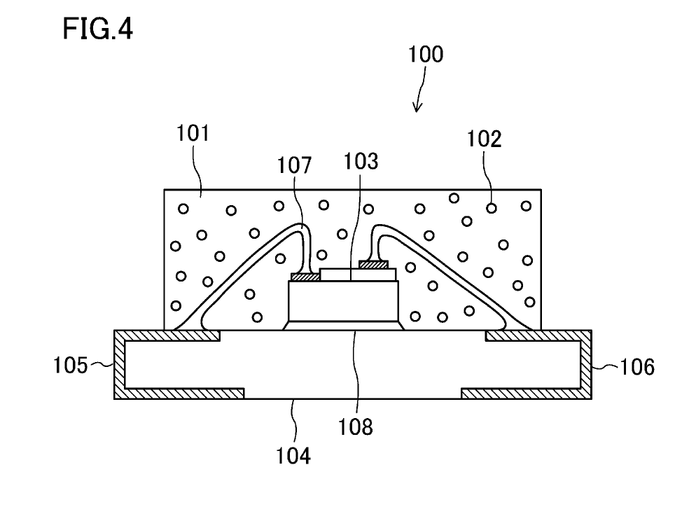

FIG. 2 is a diagram schematically illustrating a process of recombining an electron and a hole in each of the phosphors 13. As illustrated in FIG. 2, an electron excited from the valence band to the conduction band is recombined with a hole in the valence band to radiate light (radiative transition). In contrast, as illustrated in FIG. 2, the process in which an electron in the conduction band is recombined with a hole in the valence band through a surface trap state does not contribute to light radiation (nonradiative transition).

FIG. 3 is a graph illustrating the excitation intensity dependence of the transition probability in the recombination process illustrated in FIG. 2. As illustrated in FIG. 3, with increasing excitation intensity, the transition probability of the radiative transition monotonously increases while the transition probability of the nonradiative transition is saturated due to the surface trap state having a low density (defect density in the surface of each of the phosphors 13). In other words, with increasing excitation intensity, the proportion of the nonradiative transition in the recombination process decreases. Therefore, light can be emitted with high efficiency by strongly exciting the phosphors 13.

As described above, in the white light emitting device 10 of this embodiment, laser light generated from the light emitting section (AlGaInN-based VCSEL) 14 produces surface plasmons in the vicinity of the minute openings 12 of the thin metal film 11, and a locally high electric field is consequently obtained. The enhanced local electric field strongly excites the phosphors 13; therefore, as described above, the proportion of the nonradiative recombination decreases, and the efficiency of light emission can be increased, thereby obtaining fluorescence with high intensity.

Since, in particular, in this embodiment, nanophosphors (quantum dot phosphors 13a, 13b, and 13c) each having a particle size that is smaller than the diameter of each of the minute openings 12 of the thin metal film 11 are used as the phosphors 13, this can ensure the placement of the phosphors 13 in each of the minute openings 12. When, as such, the phosphors 13 can be placed in each of the minute openings 12, the phosphors 13 can be excited by, not only an electric field formed on a front surface of the thin metal film 11 (opposite to the light emitting section 14), but also an electric field formed on a back surface of the thin metal film 11 (toward the light emitting section 14) and an electric field formed in each of the minute openings 12. In the minute opening 12, with decreasing distance to the light emitting section 14, the electric field intensity of the surface plasmons increases, and thus, some of the phosphors 13 closest to the light emitting section 14 can emit light with highest efficiency.

In this embodiment, a case where the light emitting section 14 configured to convert electricity into light is an AlGaInN-based surface emitting laser was described. However, the type of the light emitting section 14 is not specifically limited as long as the light emitting section 14 is a light source capable of exciting phosphors. For example, a light emitting diode (LED) emitting light in the blue to ultraviolet wavelength range may be used.

In this embodiment, quantum dot phosphors made of CdSe are used as the phosphors 13. However, also when, instead of the quantum dot phosphors, quantum dot phosphors made of a material, such as cadmium telluride (CdTe) or cadmium sulfide (CdS), are used, advantages similar to those of this embodiment can be obtained. The phosphors 13 are not limited to quantum dot phosphors, and for example, YAG phosphors or phosphors made of an organic material may be used as the phosphors 13.

The present disclosure can provide a white light emitting device with high luminous efficacy, and the white light emitting device according to the present disclosure is preferably used in, e.g., lighting devices or displays.

What is claimed is:

1. A light emitting device comprising:
a light emitting section including an active layer configured to emit light by application of a voltage; and
a thin metal film disposed on a region of the light emitting section irradiated with the light, wherein
the thin metal film has a plurality of openings each having a diameter that is smaller than a wavelength of the light, and
at least one phosphor is placed in each of the openings.

2. The light emitting device of claim 1, wherein
the phosphor is a particle having a size equal to or less than about 100 nm.

3. The light emitting device of claim 1, wherein
the openings each have a diameter greater than or equal to about 50 nm and equal to or less than 200 nm.

4. The light emitting device of claim 1, wherein
the at least one phosphor includes three types of phosphors emitting light in blue, green, and red wavelength regions.

5. The light emitting device of claim 4, wherein
λact is less than λ1,
λact is less than λ2, and
λact is less than λ3,
where λact represents a wavelength of the light emitted by the active layer,
λ1 represents an emission wavelength of one of the phosphors emitting light in the blue wavelength region,
λ2 represents an emission wavelength of another one of the phosphors emitting light in the green wavelength region, and
λ3 represents an emission wavelength of the other one of the phosphors emitting light in the red wavelength region.

6. The light emitting device of claim 1, wherein
the phosphor is a quantum dot.

7. The light emitting device of claim 6, wherein
the quantum dot has a size greater than or equal to about 1 nm and equal to or less than 20 nm.

8. The light emitting device of claim 1, wherein
the light emitting section is a surface emitting laser,
the thin metal film is formed on the surface emitting laser, and
the phosphor is excited by laser light generated by the surface emitting laser.

9. The light emitting device of claim 1, wherein
the light emitting section is a light emitting diode,
the thin metal film is formed on the light emitting diode, and
the phosphor is excited by light generated by the light emitting diode.
